(19) United States
(12) Patent Application Publication
(10) Pub. No.: US 2003/0160282 A1
(43) Pub. Date: Aug. 28, 2003

(54) Semiconductor device

(76) Inventor: Takashi Terada, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/201,285

(22) Filed: Jul. 24, 2002

(30) Foreign Application Priority Data
Feb. 25, 2002 (JP) 2002-048631

(51) Int. Cl. H01L 29/76; H01L 29/94; H01L 31/062; H01L 31/113; H01L 31/119

(52) U.S. Cl. 257/346

(57) ABSTRACT

A semiconductor device comprises a gate insulating film formed on a semiconductor substrate, a layer insulting film formed over the gate insulating film and provided with an opening, and a gate electrode formed on the gate insulating film in the opening of the interlayer insulating film. The gate electrode has a metal film, and a poly-Si film formed on the side surfaces of the metal film. The poly-Si film coating the side surfaces of the metal film reduces stresses that may be induced in the interlayer insulating film and the metal film.

### BACKGROUND OF THE INVENTION

1. Field of the Invention

The present invention relates to a semiconductor device, and more particularly, to a semiconductor device provided with a metal gate electrode.

2. Background Art

The size of gates has been reduced with the progressive increase of the number of components per chip in recent years. A polycide structure formed by depositing a tungsten silicide film (WSi film) over a polysilicon film (Poly-Si film) is used as a generally known gate structure. Increase in the resistance of the gate electrode caused by the reduction of the size of the gate has become a problem.

A metal gate formed of a low-resistance metal is important for the development of semiconductor devices.

A conventional method of forming a metal gate will be described with reference to drawings. FIGS. 8A to 8E are typical sectional views of a workpiece in successive steps of a conventional method of fabricating a semiconductor device. As shown in FIG. 8A, a gate oxide film 102 and a metal film 103 are formed successively on a semiconductor substrate 101. A resist film is formed over the entire surface of the metal film 103, and the resist film is processed by photolithography to form a resist pattern 104 for forming gate electrodes.

As shown in FIG. 8B, the metal film 103 is then etched through the resist pattern 104 serving as a mask to form metal gate electrodes 105.

Then, as shown in FIG. 8C, the resist pattern 104 is removed, an insulating film 106 of silicon dioxide or silicon nitride is formed so as to cover the top and side surfaces of the metal gate electrodes 105.

As shown in FIG. 8D, the insulating film 106 is then etched to form side walls on the side surfaces of the metal gates 105.

As shown in FIG. 8E, the semiconductor substrate 101 is then doped by using the metal gate electrodes 105 as a mask to form source/drain diffused layers 108, and then an interlayer insulating film 107 is formed so as to cover the metal gate electrodes 105 to complete MOS transistors each provided with the low-resistance metal gate electrode 105.

The following problems arise in the conventional method because the width of lines forming the gate pattern has been progressively reduced.

In the steps shown in FIGS. 8A and 8B, loss of shape and collapse of the resist pattern occur because the lines of the resist pattern 104 for forming the gate electrodes have a very narrow width. When the metal gate electrodes 105 having a very narrow width is formed by using the resist pattern 104 as a mask, collapse of the gate electrode pattern occurs.

In the steps shown in FIGS. 8C and 8D, the shape of the metal gate electrodes 105 is deteriorated because the insulating film 106 is formed at a high temperature. The metal gate electrodes 105 react with reaction gases for forming the insulating film 106 and the resistance of the metal gate electrodes 105 is increased, which deteriorates the characteristics of devices.

Stress is induced in the metal gate electrodes 105 due to difference in thermal expansion between the metal gate electrodes 105, and the gate oxide film 102, the insulating film 106 and the interlayer insulating film 107 contiguous with the metal gate electrodes 105, which affects adversely to the reliability of the device, for example, causing the breakage of the gate electrode wiring.

### SUMMARY OF THE INVENTION

The present invention has been made in view of the foregoing problems and it is therefore a first object of the present invention to suppress the deterioration of metal gate electrodes due to the miniaturization of the meal gate electrodes and to enhance the reliability of semiconductor devices.

A second object of the present invention is to suppress the variation of the characteristics of metal gate electrodes and to improve the reliability of semiconductor devices.

According to one aspect of the present invention, a semiconductor device comprises a gate insulating film, a interlayer insulating film, and a gate electrode. The gate insulating film is formed on a semiconductor substrate. The interlayer insulating film is formed over the gate insulating film. The interlayer insulating is provided with an opening in which a part of the gate insulating film is exposed. The gate electrode is formed on the gate insulating film exposed in the opening. The gate electrode is a metal film having side surfaces coated with a stress-reducing film.

The stress-reducing film formed on the side surfaces of the metal film reduces stresses induced in the insulating film, such as the interlayer insulating film covering the gate electrode, and the metal film greatly. Therefore, the breakage of the gate electrode can be prevented and the reliability of the gate wiring can be improved.

Other and further objects, features and advantages of the invention will appear more fully from the following description.

### BRIEF DESCRIPTION OF THE DRAWINGS

FIG. 1 is a typical sectional view of the semiconductor device in the first embodiment

FIGS. 2A to 2H are typical sectional views of a workpiece in successive steps of a method of fabricating the semiconductor device in the first embodiment.

FIGS. 3A to 3H are typical sectional views of a workpiece in successive steps of a method of fabricating a semiconductor device in a second embodiment according to the present invention.

FIGS. 4A to 4G are typical sectional views of a workpiece in successive steps of a method of fabricating a semiconductor device in a third embodiment according to the present invention.

FIGS. 5A to 5G are typical sectional views of a workpiece in successive steps of a method of fabricating a semiconductor device in a fourth embodiment according to the present invention.

FIGS. 6A to 6H are typical sectional views of a workpiece in successive steps of a method of fabricating a semiconductor device in a fifth embodiment according to the present invention.

FIGS. 7A to 7H are typical sectional views of a workpiece in successive steps of a method of fabricating a semiconductor device in a sixth embodiment according to the present invention.

FIGS. 8A to 8E are typical sectional views of a workpiece in successive steps of a conventional method of fabricating a semiconductor device.

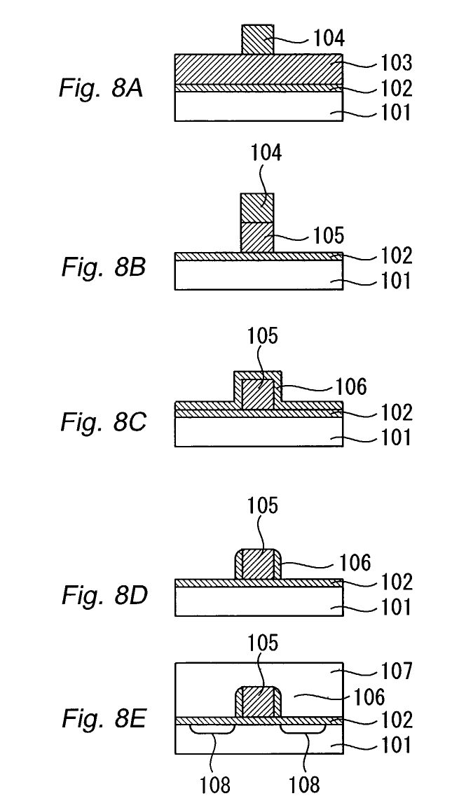

### DETAILED DESCRIPTION OF THE PREFERRED EMBODIMENTS

First Embodiment

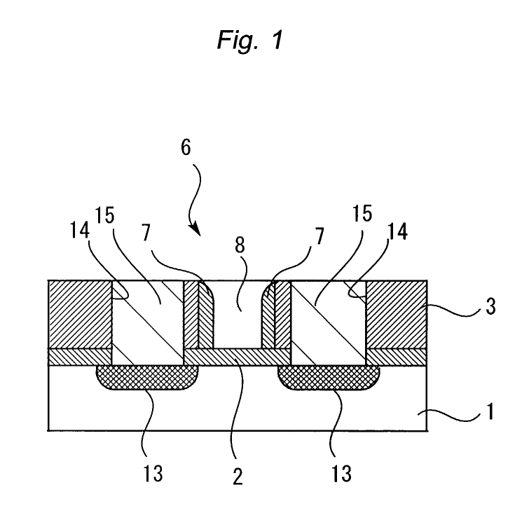

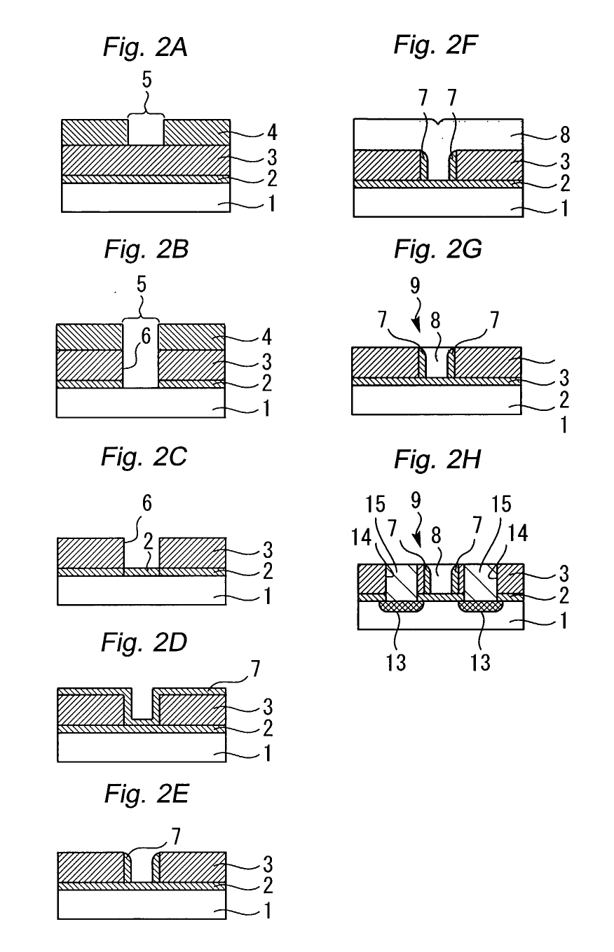

A semiconductor device in a first embodiment according to the present invention and a method of fabricating the same will be described with reference to FIGS. 1 and 2. FIG. 1 is a typical sectional view of the semiconductor device in the first embodiment, and FIGS. 2A to 2H are typical sectional views of a workpiece in successive steps of a method of fabricating the semiconductor device in the first embodiment.

The configuration of the semiconductor device in the first embodiment will be described with reference to FIG. 1. A gate insulating film 2 is deposited on a semiconductor substrate 1, and a interlayer insulating film 3 is formed over the gate insulating film 2. The interlayer insulating film 3 is provided in predetermined regions thereof with a linear opening 6. A metal film 8 of a metal, such as tungsten (W) is formed in the opening 6. Side surfaces of the metal film 8 are coated with a nondoped poly-Si film 7. Source/drain diffused layers 13 are formed in surface regions of the semiconductor substrate 1 on the opposite sides of the metal film 8, respectively. Openings 14 are formed in portions corresponding to the source/drain diffused layers 13 of the interlayer insulating film 3, and contact layers 15 are formed in the openings 14 so as to be electrically connected to the source/drain diffused layers 13, respectively. The metal film 8 formed in the opening 6 serves as a low-resistance metal gate electrode 9 for a MOS transistor.

The construction and a method of fabricating the semiconductor device in the first embodiment will be described with reference to FIG. 2.

As shown in FIG. 2A, the gate insulating film 2 and the interlayer insulating film 3 are formed successively on the semiconductor substrate 1. The interlayer insulating film 3 is then coated entirely with a resist film. The resist film is processed by photolithography to form a resist pattern 4 for forming the gate electrode. The resist pattern 4 has an opening in the gate electrode forming portion 5.

Next, as shown in FIG. 2B, a part corresponding to the gate electrode forming portion 5 of the interlayer insulating film 3 is etched by dry etching using the resist pattern 4 as an etching mask so that the upper surface of the gate insulating film 2 is exposed. Subsequently, a part corresponding to the gate electrode forming portion 5 and damaged by dry etching of the gate insulating film 2 is removed by wet etching to complete the opening 6 in the interlayer insulating film 3.

Then, as shown in FIG. 2C, the gate insulating film 2 is formed on the exposed part corresponding to the gate electrode forming portion 5 of the upper surface of the semiconductor substrate 1. Desirably, the gate insulating film is an insulating film, such as a silicon dioxide film or a SiON film.

Then, as shown in FIG. 2D, the nondoped poly-Si film 7 is deposited so as to cover the interlayer insulating film 3, and the bottom and side surfaces of the opening 6.

Then, as shown in FIG. 2E, parts of the poly-Si film 7 covering the upper surface of the interlayer insulating film 3, and the bottom of the opening 6 are removed by anisotropic etching, so that the poly-Si film 7 remains as a stress-reducing film only on the side surfaces of the opening 6.

Then, as shown in FIG. 2F, the metal film 8 is deposited so as to cover the interlayer insulating film 3 and to fill up the opening 6 by a film forming process excellent in coating performance, such as a CVD process or a reflow sputtering process that performs heat treatment after sputtering. The metal film 8 is formed of, for example, tungsten (W).

Then, as shown in FIG. 2G, the metal film 8 is polished or etched by a chemical/mechanical polishing process (CMP process) or an etchback process so that the surface of the interlayer insulating film 3 is exposed. Thus, the poly-Si film 7, the metal film 8 and the poly-Si film 7 are arranged horizontally in that order on the semiconductor substrate 1 to form the metal gate electrode 9.

Subsequently, as shown in FIG. 2H, the openings 14 reaching the surface of the semiconductor substrate 1 are formed in the interlayer insulating film 3 on the opposite sides of the metal gate electrode 9, respectively. Then, the source/drain-diffused layers 13 are formed in the semiconductor substrate 1 on the opposite sides, respectively, of the metal gate electrode 9 by ion implantation or the like. Then, the openings 14 are filled up with tungsten or the like to form the contact layers 15 connected to the source/drain diffused layers 13. Thus, the MOS transistor shown in FIG. 1 is completed.

If the metal gate is a tungsten film formed by, for example, a CVD process, the metal gate has a high tensile stress on the order of 1×10⁹ dyne/cm². Consequently, high stresses are induced in the metal gate and the adjacent insulating film. Since the metal film 8 is sandwiched between the poly-Si films 7, which induces stress scarcely as compared with a metal film, such as a tungsten film, in the first embodiment, stresses in the interlayer insulating film 3 and the metal film 8 can be greatly reduced. Thus, the breakage of the metal gate electrode 9 can be prevented and the reliability of the gate wiring can be improved.

Since the electrical characteristics of the transistor is dependent on the metal film because the nondoped poly-Si film 7 has a low conductivity, the poly-Si film 7 does not affect the characteristics of the transistor. Thus, the reliability of the metal gate electrode 9 can be improved without deteriorating the characteristics of the transistor. Moreover, the metal gate electrode 9 can be formed in a width substantially smaller than that of the opening 6, which is advantageous to the miniaturization of the device.

Since the metal gate electrode 9 is formed in the opening 6 corresponding to the gate electrode forming portion 5, any very narrow resist pattern does not need to form the very narrow gate electrode. Therefore, loss of shape of the resist pattern for forming the gate can be prevented and the very narrow metal gate electrode 9 can be steadily formed. Since the pattern is not isolated after the formation of the metal gate electrode 9, the collapse of the pattern can be prevented.

When the gate electrode is formed of, for example, tungsten which is oxidized easily in an oxidizing atmosphere of 350° C. or more, the gate electrode is oxidized and the resistance of the gate wiring increases. Since the metal film 8 is formed after forming the interlayer insulating film 3 in the first embodiment, the deformation of the metal gate electrode 9 can be prevented, and the reaction of reaction gases used for forming the insulating film, such as an oxide film or a nitride film, on the metal gate electrode 9 with the metal gate electrode 9 can be prevented.

Second Embodiment

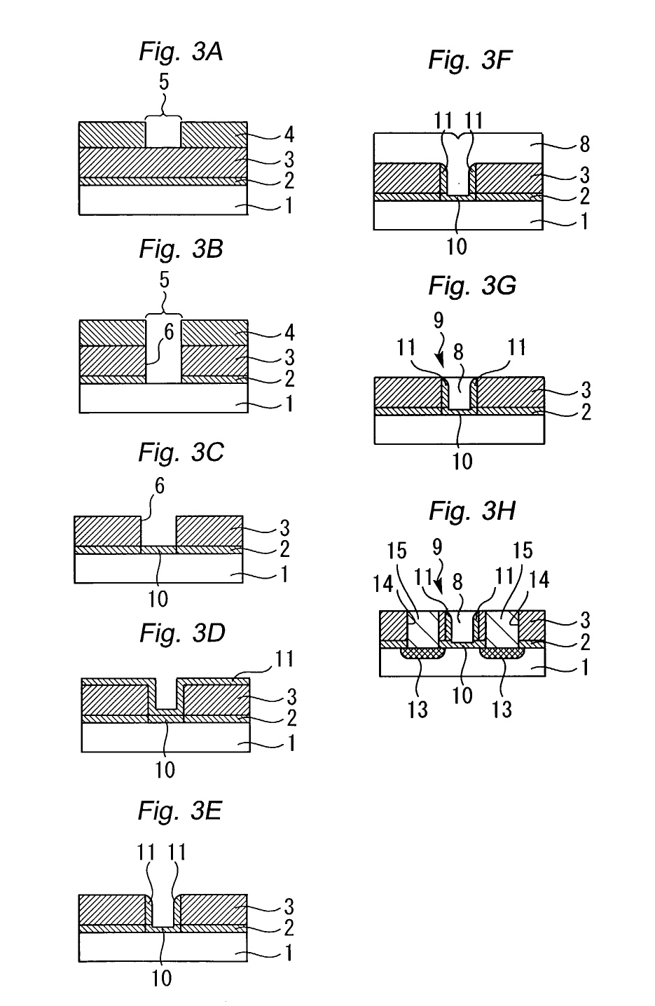

FIGS. 3A to 3H are typical sectional views of a workpiece in successive steps of a method of fabricating a semiconductor device in a second embodiment according to the present invention. In the second embodiment, a doped poly-Si film is formed on the metal gate. The construction and a method of fabricating the semiconductor device in the second embodiment will be described with reference to FIGS. 3A to 3H, in which component parts like or corresponding to those of the first embodiment are denoted by the same reference characters.

As shown in FIG. 3A, a gate insulating film 2 and a interlayer insulating film 3 are formed successively on a semiconductor substrate 1. Then, the interlayer insulating film 3 is coated entirely with a resist film. The resist film is processed by photolithography to form a resist pattern 4 for forming a gate electrode. The resist pattern 4 has an opening in the gate electrode forming portion 5.

Then, as shown in FIG. 3B, a part corresponding to the gate electrode forming portion 5 of the interlayer insulating film 3 is etched by dry etching using the resist pattern 4 as an etching mask so that the upper surface of the gate insulating film 2 is exposed. Subsequently, a part corresponding to the gate electrode forming portion 5 and damaged by dry etching of the gate insulating film 2 is removed by wet etching to complete an opening 6 in the interlayer insulating film 3.

Then, as shown in FIG. 3C, a gate insulating film 10 of a thickness greater than a desired thickness is formed on the exposed part corresponding to the gate electrode forming portion 5 of the upper surface of the semiconductor substrate 1. Desirably, the gate insulating film 10, as well as the gate insulating film 2, is an insulating film, such as a silicon dioxide film or a SiON film.

Then, as shown in FIG. 3D, a doped poly-Si film 11 is deposited so as to cover the interlayer insulating film 3, and the bottom and side surfaces of the opening 6. A doped poly-Si film may be deposited, or a nondoped poly-Si film may be formed and the nondoped poly-Si film may be doped by ion implantation or the like to form the highly conductive poly-Si film 11.

Then, as shown in FIG. 3E, parts of the poly-Si film 11 covering the upper surface of the interlayer insulating film 3, and the bottom of the opening 6 are removed to some extent by anisotropic etching. Subsequently, the remaining poly-Si film 11 is etched by wet etching capable of selectively etching the poly-Si film 11 at a high etch selectivity relative to the gate insulating film 10 so that the poly-Si film 11 remains as an stress-reducing film only on the side surfaces of the opening 6.

The gate insulating film 10 is etched by a depth in the range of several angstroms to several tens angstroms by the wet etching. Therefore, the gate insulating film 10 is formed in a thickness determined taking into consideration the reduction of the thickness thereof by the wet etching. Thus, the thickness of parts of the gate insulating film 10 underlying the poly-Si film 11 is greater than that of a part of the gate insulating film 10 exposed in the opening 6.

Then, as shown in FIG. 3F, a metal film 8 is deposited so as to cover the interlayer insulating film 3 and to fill up the opening 6 corresponding to the gate electrode forming portion 5 by a film forming process excellent in coating performance, such as a CVD process or a reflow sputtering process that performs heat treatment after sputtering. The metal film 8 is formed of, for example, tungsten (W).

Then, as shown in FIG. 3G, the metal film 8 is polished or etched by a CMP process or an etchback process so that the surface of the interlayer insulating film 3 is exposed. Thus, the poly-Si film 11, the metal film 8 and the poly-Si film 11 are arranged horizontally in that order on the semiconductor substrate 1 to form a metal gate electrode 9.

Subsequently, as shown in FIG. 3H, openings 14 reaching the surface of the semiconductor substrate 1 are formed in the interlayer insulating film 3 on the opposite sides of the metal gate electrode 9, respectively. Then, source/drain diffused layers 13 are formed in the semiconductor substrate 1 on the opposite sides, respectively, of the metal gate electrode 9 by ion implantation or the like. Then, the openings 14 are filled up with tungsten or the like to form contact layers 15 connected to the source/drain diffused layers 13. Thus, a MOS transistor is completed.

In the semiconductor device in the second embodiment, parts of the gate insulating film 10 underlying the poly-Si films 11 can be formed in a thickness greater than that of a part of the gate insulating film 10 underlying the metal film 8. Therefore, generation of hot carriers in the vicinity of the drain of the MOS transistor can be prevented and thereby the reliability of the transistor can be improved.

Since the metal film 8 is sandwiched between the poly-Si films 11, which scarcely induces stress as compared with the metal film, such as a tungsten film, stresses in the interlayer insulating film 3 and the metal film 8 can be greatly reduced. Thus, the breakage of the metal gate electrode 9 can be prevented and the reliability of the gate wiring can be improved.

Since the metal gate electrode 9 is formed in the opening 6 corresponding to the gate electrode forming portion 5, any very narrow resist pattern does not need to form the very narrow gate electrode. Therefore, loss of shape of the resist pattern for forming the gate can be prevented and the very narrow metal gate electrode 9 can be steadily formed. Since the pattern is not isolated after the formation of the metal gate electrode 9, the collapse of the pattern can be prevented.

Since the interlayer insulating film 3 is formed first, and then the metal film 8 is formed, the deformation of the metal gate electrode can be prevented, and the reaction of reaction gases used for forming the insulating film, such as an oxide film or a nitride film, on the metal gate electrode 9 with the metal gate electrode 9 can be prevented.

Third Embodiment

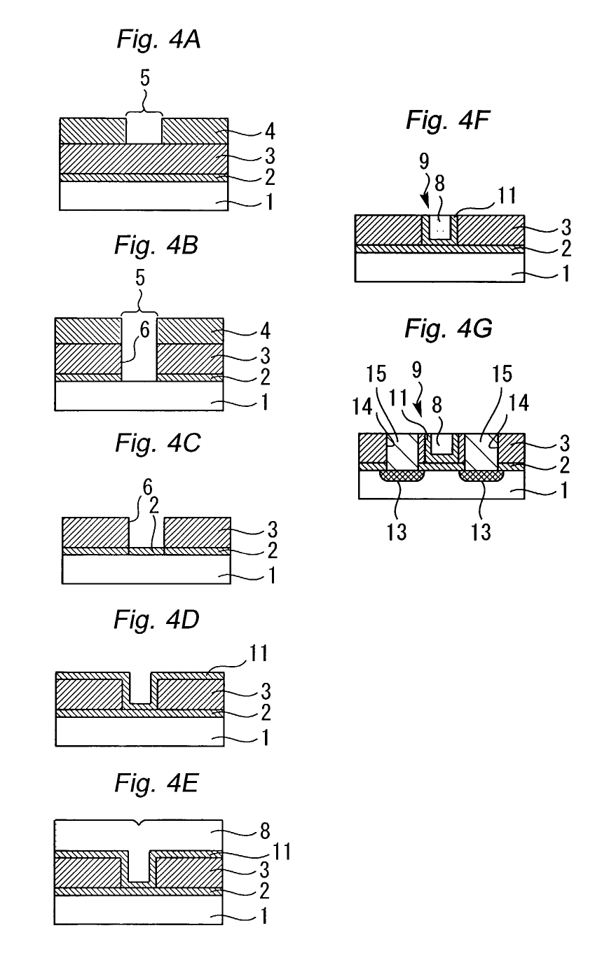

FIGS. 4A to 4G are typical sectional views of a workpiece in successive steps of a method of fabricating a semiconductor device in a third embodiment according to the present invention. This method does not include a step of etching back a poly-Si film, and forms a structure having a metal film and poly-Si films coating the side surfaces and bottom of the metal film. The construction and the method of fabricating the semiconductor device in the third embodiment will be described with reference to FIGS. 4A to 4G, in which component parts like or corresponding to those of the foregoing embodiments are denoted by the same reference characters.

As shown in FIG. 4A, a gate insulating film 2 and a interlayer insulating film 3 are formed successively on a semiconductor substrate 1. Then, the interlayer insulating film 3 is coated entirely with a resist film. The resist film is processed by photolithography to form a resist pattern 4 for forming a gate electrode. The resist pattern 4 has an opening in the gate electrode forming portion 5.

Then, as shown in FIG. 4B, a part corresponding to the gate electrode forming portion 5 of the interlayer insulating film 3 is etched by dry etching using the resist pattern 4 as an etching mask so that the upper surface of the gate insulating film 2 is exposed. Subsequently, a part corresponding to the gate electrode forming portion 5 and damaged by dry etching of the gate insulating film 2 is removed by wet etching to complete an opening 6 in the interlayer insulating film 3.

Then, as shown in FIG. 4C the gate insulating film 2 is formed again on a part of the substrate 1 corresponding to the gate electrode forming portion 5.

Then, as shown in FIG. 4D, a doped poly-Si film 11 is deposited so as to cover the interlayer insulating film 3, and the bottom and side surfaces of the opening 6. A doped poly-Si film may be deposited, or a nondoped poly-Si film may be formed and the nondoped poly-Si film may be doped by ion implantation or the like to form the highly conductive poly-Si film 11.

Then, as shown in FIG. 4E, a metal film 8 is deposited so as to cover the interlayer insulating film 3 and to fill up the opening 6 corresponding to the gate electrode forming portion 5 by a film forming process excellent in coating performance, such as a CVD process or a reflow sputtering process that performs heat treatment after sputtering. The metal film 8 is formed of, for example, tungsten (W).

Then, as shown in FIG. 4F, the metal film 8 is polished or etched by a CMP process or an etchback process so that the poly-Si film 11 coating the interlayer insulating film 3 is removed. Thus, the surface of the interlayer insulating film 3 is exposed and, as shown in FIG. 4F, a metal gate layer 9 including the metal film 8 having side surfaces and bottom surface coated with the doped poly-Si film 11 is formed.

Subsequently, as shown in FIG. 4G, openings 14 reaching the surface of the semiconductor substrate 1 are formed in the interlayer insulating film 3 on the opposite sides of the metal gate electrode 9, respectively. Then, source/drain diffused layers 13 are formed in the semiconductor substrate 1 on the opposite sides, respectively, of the metal gate electrode 9 by ion implantation or the like. Then, the openings 14 are filled up with tungsten or the like to form contact layers 15 connected to the source/drain diffused layers 13. Thus, a MOS transistor is completed.

Since the side surfaces and bottom surface of the metal film 8 are coated with the doped poly-Si films 11, stresses not only in the interlayer insulating film 3, the metal film 8, but also in the metal film 8 and the gate insulating film 2 can be reduced. Thus, the reliability of the gate wiring and the gate electrode can be improved.

Since etching is not necessary after the formation of the poly-Si film 11, the number of steps can be cut down and hence costs can be reduced.

A dual gate can be formed when necessary by doping the poly-Si film 11 with either a p-type or an n-type impurity. Therefore the performance of the MOS transistor can be enhanced to improve device performance.

Since the side surfaces of the metal film 8 are coated with the poly-Si films 11, which scarcely induces stress as compared with a metal film, such as a tungsten film, stresses in the interlayer insulating film 3 and the metal film 8 can be greatly reduced. Thus, the breakage of the metal gate electrode 9 can be prevented and the reliability of the gate wiring can be improved.

Since the metal gate electrode 9 is formed in the opening 6 corresponding to the gate electrode forming portion 5, any very narrow resist pattern does not need to form the very narrow gate electrode. Therefore, loss of shape of the resist pattern for forming the gate can be prevented and the very narrow metal gate electrode 9 can be steadily formed. Since the pattern is not isolated after the formation of the metal gate electrode 9, the collapse of the pattern can be prevented.

Since the interlayer insulating film 3 is formed first, and then the metal film 8 is formed, the deformation of the metal gate electrode can be prevented, and the reaction of reaction gases used for forming the insulating film, such as an oxide film or a nitride film, on the metal gate electrode 9 with the metal gate electrode 9 can be prevented.

Fourth Embodiment

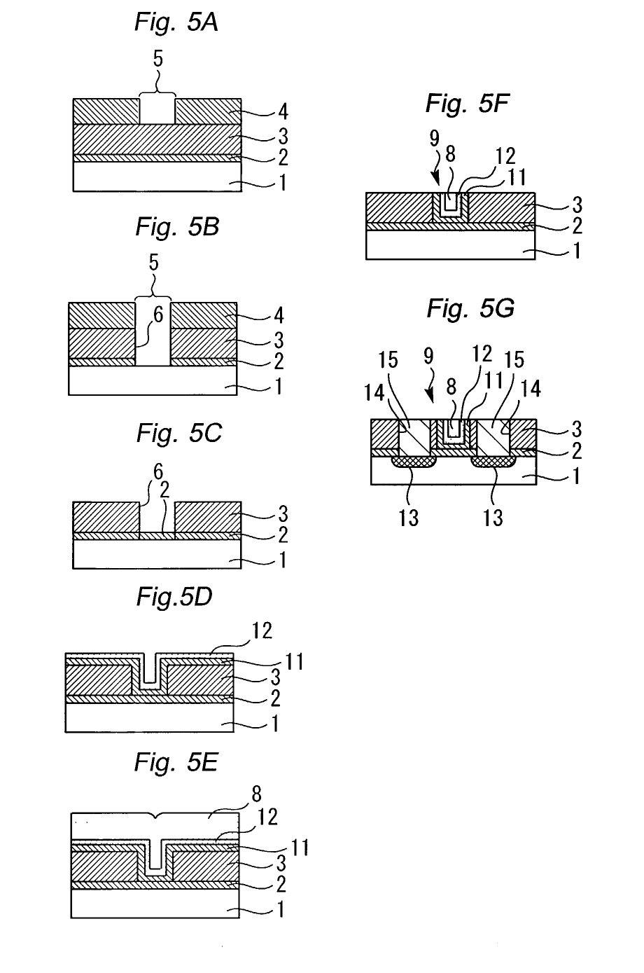

FIGS. 5A to 5G are typical sectional views of a workpiece in successive steps of a method of fabricating a semiconductor device in a fourth embodiment according to the present invention. In the fourth embodiment, the side surfaces and the bottom surface of a metal gate are coated with a barrier metal film, and the barrier metal film is coated with a poly-Si film. The construction and a method of fabricating the semiconductor device in the fourth embodiment will be described with reference to FIGS. 5A to 5G.

As shown in FIG. 5A, a gate insulating film 2 and a interlayer insulating film 3 are formed successively on a semiconductor substrate 1. Then, the interlayer insulating film 3 is coated entirely with a resist film. The resist film is processed by photolithography to form a resist pattern 4 for forming a gate electrode. The resist pattern 4 has an opening in the gate electrode forming portion 5.

Then, as shown in FIG. 5B, a part corresponding to the gate electrode forming portion 5 of the interlayer insulating film 3 is etched by dry etching using the resist pattern 4 as an etching mask so that the upper surface of the gate insulating film 2 is exposed. Subsequently, a part corresponding to the gate electrode forming portion 5 and damaged by dry etching of the gate insulating film 2 is removed by wet etching to complete an opening 6 in a part corresponding to the gate electrode forming portion 5 of the interlayer insulating film 3.

Then, as shown in FIG. 5C a gate insulating film 2 is formed again on a part of the substrate 1 corresponding to the gate electrode forming portion 5.

Then, as shown in FIG. 5D, a doped poly-Si film 11 is deposited so as to cover the interlayer insulating film 3, and the bottom and side surfaces of the opening 6, and a barrier metal film 12 as a reaction preventing film is formed over the doped poly-Si film 11. A doped poly-Si film may be deposited, or a nondoped poly-Si film may be formed and the nondoped poly-Si film may be doped by ion implantation or the like to form the highly conductive poly-Si film 11. The barrier metal film 12 is formed by a sputtering process or a CVD process excellent in coating performance. The barrier metal film 12 is formed of, for example, tungsten nitride (WNₓ).

Then, as shown in FIG. 5E, a metal film 8 is deposited so as to fill up the opening 6 corresponding to the gate electrode forming portion 5 by a film forming process excellent in coating performance, such as a CVD process or a reflow sputtering process that performs heat treatment after sputtering. The metal film 8 is formed of, for example, tungsten (W).

Then, as shown in FIG. 5F, the metal film 8, the barrier metal film 12 and the poly-Si film 11 are polished or etched by a CMP process or an etchback process so that the poly-Si film 11 coating the interlayer insulating film 3 is removed. Thus, the surface of the interlayer insulating film 3 is exposed and, as shown in FIG. 5F, a metal gate layer 9 including the metal film 8 having side surfaces and bottom surface coated with the barrier metal film 12 and the doped poly-Si film 11 is formed.

Subsequently, as shown in FIG. 5G, openings 14 reaching the surface of the semiconductor substrate 1 are formed in the interlayer insulating film 3 on the opposite sides of the metal gate electrode 9, respectively. Then, source/drain diffused layers 13 are formed in the semiconductor substrate 1 on the opposite sides, respectively, of the metal gate electrode 9 by ion implantation or the like. Then, the openings 14 are filled up with tungsten or the like to form contact layers 15 connected to the source/drain diffused layers 13. Thus, a MOS transistor is completed.

According to the forth embodiment, since the side surfaces and bottom surface of the metal film 8 are coated with the doped poly-Si films 11, stresses not only in the interlayer insulating film 3 and the metal film 8, but also in the metal film 8 and the gate insulating film 2 can be reduced. The barrier metal film 12 formed between the poly-Si film 11 and the metal film 8 reduces resistance between the poly-Si film 11 and the metal layer 8, prevents reaction between the poly-Si film 11 and the metal film 8, and enhances adhesion between the poly-Si film 11 and the metal film 8. Thus, the reliability of the gate wiring and the gate electrode 9 can be improved.

Since etching is not necessary after the formation of the poly-Si film 11, the number of steps can be cut down and hence costs can be reduced.

A dual gate can be formed when necessary by doping the poly-Si film 11 with either a p-type or an n-type impurity. Therefore the performance of the MOS transistor can be enhanced to improve device performance.

Since the side surfaces of the metal film 8 are coated with the poly-Si films 11, which scarcely induces stress as compared with a metal film, such as a tungsten film, stresses in the interlayer insulating film 3 and the metal film 8 can be greatly reduced. Thus, the breakage of the metal gate electrode 9 can be prevented and the reliability of the gate wiring can be improved.

Since the metal gate electrode 9 is formed in the opening 6 corresponding to the gate electrode forming portion 5, any very narrow resist pattern does not need to form the very narrow gate electrode. Therefore, loss of shape of the resist pattern for forming the gate can be prevented and the very narrow metal gate electrode 9 can be steadily formed. Since the pattern is not isolated after the formation of the metal gate electrode 9, the collapse of the pattern can be prevented.

Since the interlayer insulating film 3 is formed first, and then the metal film 8 is formed, the deformation of the metal gate electrode can be prevented, and the reaction of reaction gases used for forming the insulating film, such as an oxide film or a nitride film, on the metal gate electrode 9 with the metal gate electrode 9 can be prevented.

Fifth Embodiment

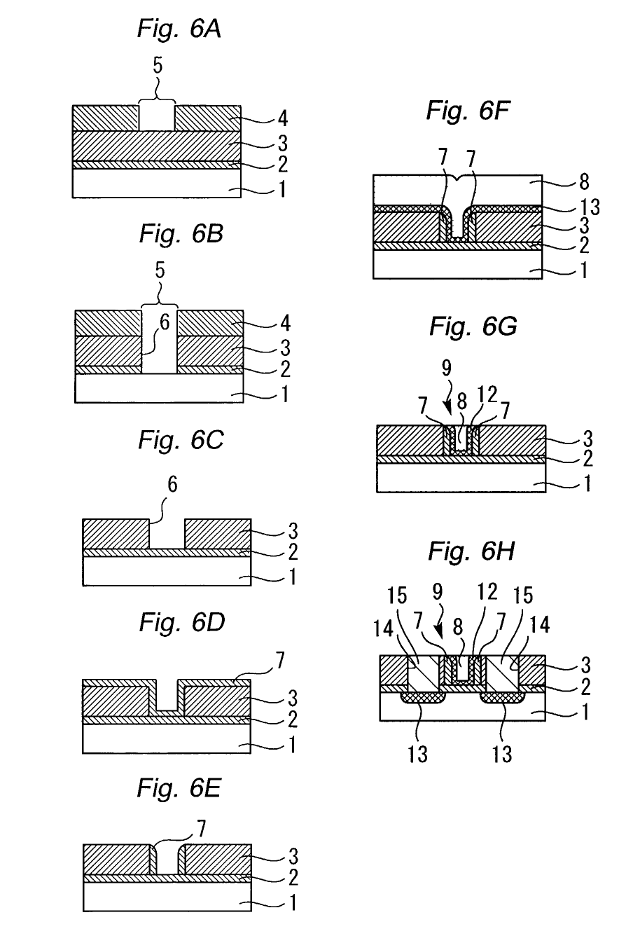

FIGS. 6A to 6H are typical sectional views of a workpiece in successive steps of a method of fabricating a semiconductor device in a fifth embodiment according to the present invention. In the fifth embodiment, a barrier metal film is formed between the poly-Si film 7 and the metal film 8 of the first embodiment. The construction and a method of fabricating the semiconductor device in the fifth embodiment will be described with reference to FIGS. 6A to 6H.

As shown in FIG. 6A, a gate insulating film 2 and a interlayer insulating film 3 are formed successively on a semiconductor substrate 1. Then, the interlayer insulating film 3 is coated entirely with a resist film. The resist film is processed by photolithography to form a resist pattern 4 for forming a gate electrode. The resist pattern 4 has an opening in the gate electrode forming portion 5.

Then, as shown in FIG. 6B, a part corresponding to the gate electrode forming portion 5 of the interlayer insulating film 3 is etched by dry etching using the resist pattern 4 as an etching mask so that the upper surface of the gate insulating film 2 is exposed. Subsequently, a part corresponding to the gate electrode forming portion 5 and damaged by dry etching of the gate insulating film 2 is removed by wet etching to complete an opening 6 in the interlayer insulating film 3.

Then, as shown in FIG. 6C, the gate insulating film 2 is formed again on a part of the substrate 1 corresponding to the gate electrode forming portion 5.

Then, as shown in FIG. 6D, a nondoped poly-Si film 7 is deposited so as to cover the interlayer insulating film 3, and the bottom and side surfaces of the opening 6.

Then, as shown in FIG. 6E, parts of the poly-Si film 7 covering the upper surface of the interlayer insulating film 3, and the bottom of the opening 6 are removed by anisotropic etching, so that the poly-Si film 7 remains only on the side surfaces of the opening 6.

Then, as shown in FIG. 6F, a barrier metal film 12 as a reaction preventing film is formed in the opening 6 and over the interlayer insulating film 3. The barrier metal film 12 is formed of, for example, a tungsten nitride by a sputtering process or a CVD process excellent in covering performance.

Then, a metal film 8 is deposited so as to fill up the opening 6 corresponding to the gate electrode forming portion 5 by a film forming method excellent in covering performance, such as a CVD process or a reflow sputtering process that performs heat treatment after sputtering. The metal film 8 is formed of, for example, tungsten (W).

Then, as shown in FIG. 6G, the barrier metal film 12 and the metal film 8 formed on the interlayer insulating film 3 are polished or etched by a CMP process or an etchback process so that the surface of the interlayer insulating film 3 is exposed. Thus, the poly-Si film 7, the barrier metal film 12, the metal film 8, the barrier metal film 12 and the poly-Si film 7 are arranged horizontally in that order on the semiconductor substrate 1 as shown in FIG. 6G to form a metal gate electrode 9.

Subsequently, as shown in FIG. 6H, openings 14 reaching the surface of the semiconductor substrate 1 are formed in the interlayer insulating film 3 on the opposite sides of the metal gate electrode 9, respectively. Then, source/drain diffused layers 13 are formed in the semiconductor substrate 1 on the opposite sides, respectively, of the metal gate electrode 9 by ion implantation or the like. Then, the openings 14 are filled up with tungsten or the like to form contact layers 15 connected to the source/drain diffused layers 13. Thus, a MOS transistor is completed.

In the fifth embodiment, the barrier metal film 12 formed between the poly-Si film 7 and the metal layer 8 prevents reaction between the poly-Si film 7 and the metal film 8 and enhances adhesion between the poly-Si film 7 and the metal film 8.

Since the electrical characteristics of the transistor is dependent on the metal film 8 because the nondoped poly-Si film 7 has a low conductivity, the poly-Si film 7 does not affect the characteristics of the transistor. Thus, the reliability of the metal gate electrode 9 can be improved without deteriorating the characteristics of the transistor. Moreover, the metal gate electrode 9 can be formed in a width substantially smaller than that of the opening 6, which is advantageous to the miniaturization of the device.

Since the metal film 8 is sandwiched between the poly-Si films 7, which scarcely induce stress as compared with a metal film, such as a tungsten film, stresses in the interlayer insulating film 3 and the metal film 8 can be greatly reduced. Thus, the breakage of the metal gate electrode 9 can be prevented and the reliability of the gate wiring can be improved.

Since the metal gate electrode 9 is formed in the opening 6 corresponding to the gate electrode forming portion 5, any very narrow resist pattern does not need to form the very narrow gate electrode. Therefore, loss of shape of the resist pattern for forming the gate can be prevented and the very narrow metal gate electrode 9 can be steadily formed. Since the pattern is not isolated after the formation of the metal gate electrode 9, the collapse of the pattern can be prevented.

Since the interlayer insulating film 3 is formed first, and then the metal film 8 is formed, the deformation of the metal gate electrode can be prevented, and the reaction of reaction gases used for forming the insulating film, such as an oxide film or a nitride film, on the metal gate electrode 9 with the metal gate electrode 9 can be prevented.

Sixth Embodiment

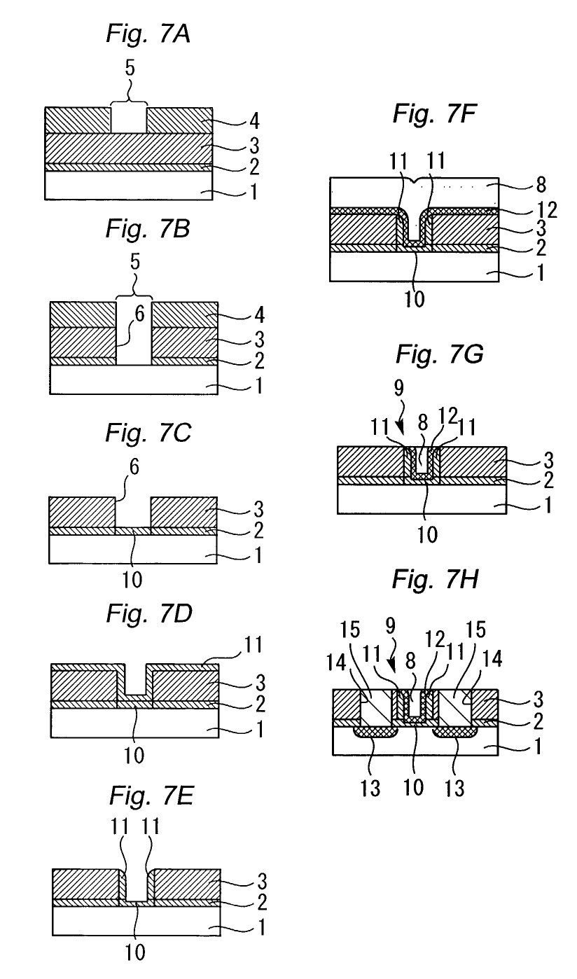

FIGS. 7A to 7H are typical sectional views of a workpiece in successive steps of a method of fabricating a semiconductor device in a sixth embodiment according to the present invention. In the sixth embodiment, a barrier metal film is formed between the poly-Si film 11 and the metal film 8 of the second embodiment. The construction and a method of fabricating the semiconductor device in the fifth embodiment will be described with reference to FIGS. 7A to 7H.

As shown in FIG. 7A, a gate insulating film 2 and a interlayer insulating film 3 are formed successively on a semiconductor substrate 1. Then, the interlayer insulating film 3 is coated entirely with a resist film. The resist film is processed by photolithography to form a resist pattern 4 for forming a gate electrode. The resist pattern 4 has an opening in the gate electrode forming portion 5.

Then, as shown in FIG. 7B, a part corresponding to the gate electrode forming portion 5 of the interlayer insulating film 3 is etched by dry etching using the resist pattern 4 as an etching mask so that the upper surface of the gate insulating film 2 is exposed. Subsequently, a part corresponding to the gate electrode forming portion 5 and damaged by dry etching of the gate insulating film 2 is removed by wet etching to complete an opening 6 in the interlayer insulating film 3.

Then, as shown in FIG. 7C, a gate insulating film 10 is formed again on a part of the substrate 1 corresponding to the gate electrode forming portion 5.

Then, as shown in FIG. 7D, a doped poly-Si film 11 is deposited so as to cover the interlayer insulating film 3, and the bottom and side surfaces of the opening 6. The doped poly-Si film 11 may be deposited, or a nondoped poly-Si film may be deposited and the nondoped poly-Si film may be doped by ion implantation or the like to form the highly conductive poly-Si film 11.

Then, as shown in FIG. 7E, parts of the poly-Si film 11 covering the upper surface of the interlayer insulating film 3 and the bottom of the opening 6 are removed to some extent by anisotropic etching. Subsequently, the remaining poly-Si film 11 is etched by wet etching capable of selectively etching the poly-Si film 11 at a high etch selectivity relative to the gate insulating film 10 so that the poly-Si film 11 remains only on the side surfaces of the opening 6 without causing damage to the gate insulating film 10.

Then, as shown in FIG. 7F, a barrier metal film 12 is formed in the opening 6 and over the interlayer insulating film 3. The barrier metal film 12 is formed of, for example, a tungsten nitride by a sputtering process or a CVD process excellent in covering performance.

Then, a metal film 8 is deposited so as to fill up the opening 6 corresponding to the gate electrode forming portion 5 by a film forming method excellent in covering performance, such as a CVD process or a reflow sputtering process that performs heat treatment after sputtering. The metal film 8 is formed of, for example, tungsten (W).

Then, as shown in FIG. 7G, the barrier metal film 12 and the metal film 8 formed on the interlayer insulating film 3 are polished or etched by a CMP process or an etchback process so that the surface of the interlayer insulating film 3 is exposed. Thus, the poly-Si film 11, the barrier metal film 12, the metal film 8, the barrier metal film 12 and the poly-Si film 11 are arranged horizontally in that order on the semiconductor substrate 1 as shown in FIG. 7G to form a metal gate electrode 9.

Subsequently, as shown in FIG. 7H, openings 14 reaching the surface of the semiconductor substrate 1 are formed in the interlayer insulating film 3 on the opposite sides of the metal gate electrode 9, respectively. Then, source/drain diffused layers 13 are formed in the semiconductor substrate 1 on the opposite sides, respectively, of the metal gate electrode 9 by ion implantation or the like. Then, the openings 14 are filled up with tungsten or the like to form contact layers 15 connected to the source/drain diffused layers 13. Thus, a MOS transistor is completed.

In the sixth embodiment, the barrier metal film 12 formed between the poly-Si film 11 and the metal layer 8 prevents reaction between the poly-Si film 11 and the metal film 8 and enhances adhesion between the poly-Si film 11 and the metal film 8.

In the semiconductor device in the sixth embodiment, parts of the gate insulating film 10 underlying the poly-Si films 11 can be formed in a thickness greater than that of a part of the gate insulating film 10 underlying the metal film 8. Therefore, generation of hot carriers in the vicinity of the drain of the MOS transistor can be prevented and thereby the reliability of the transistor can be improved.

Since the metal film 8 is sandwiched between the poly-Si films 11, which scarcely induce stress as compared with a metal film, such as a tungsten film, stresses in the interlayer insulating film 3 and the metal film 8 can be greatly reduced. Thus, the breakage of the metal gate electrode 9 can be prevented and the reliability of the gate wiring can be improved.

Since the metal gate electrode 9 is formed in the opening 6 corresponding to the gate electrode forming portion 5, any very narrow resist pattern does not need to form the very narrow gate electrode. Therefore, loss of shape of the resist pattern for forming the gate can be prevented and the very narrow metal gate electrode 9 can be steadily formed. Since the pattern is not isolated after the formation of the metal gate electrode 9, the collapse of the pattern can be prevented.

Since the interlayer insulating film 3 is formed first, and then the metal film 8 is formed, the deformation of the metal gate electrode can be prevented, and the reaction of reaction gases used for forming the insulating film, such as an oxide film or a nitride film, on the metal gate electrode 9 with the metal gate electrode 9 can be prevented.

The poly-Si films 7 of the first and the fifth embodiment serving as stress-reducing or reaction-preventing films may be substituted by a SiON film or an amorphous Si film. A SiON film or an amorphous Si film, similarly to a poly-Si film 7, induces stress scarcely as compared with a metal film, stresses in the interlayer insulating film 3 and the metal film 8 can be reduced. Thus, the reliability of the gate wiring can be improved.

Since the gate insulating film 2 is interposed between the stress-reducing film (poly-Si film 7 or 11) or the reaction-preventing film (barrier metal film 12), and the semiconductor substrate 1 in the foregoing embodiments, the performance of the MOS transistor is not affected by the stress-reducing film or the reaction-preventing film.

Although the stress-reducing film (poly-Si film 7 or 11) or the reaction-preventing film (barrier metal film 12) is formed on both the side surfaces of the metal film 8 in the foregoing embodiments, the same may be formed only on one of the side surfaces of the metal film 8.

As apparent from the foregoing description, the present invention exercises the following effects.

The stress-reducing film formed on the side surfaces of the metal film reduces stresses induced in the insulating film, such as the interlayer insulating film covering the gate electrode, and the metal film greatly. Therefore, the breakage of the gate electrode can be prevented and the reliability of the gate wiring can be improved.

The nondoped poly-Si film used as a stress-reducing film does not affect the characteristics of the transistor significantly and improves the reliability of the gate electrode without adversely affecting the characteristics of the transistor.

The conductive, doped poly-Si film used as a stress-reducing film contributes to the improvement of the electrical characteristics of the gate electrode.

Formation of the part of the gate insulating film underlying the stress-reducing film in a thickness greater than that of the part of the same underlying the metal film prevents the generation of hot carriers in the vicinity of the drain of the MOS transistor, so that the reliability of the transistor can be improved.

When the stress-reducing film is formed so as to cover the side surfaces and bottom surface of the metal film, stresses induced in the metal film and the gate insulating film, as well as those induced in the metal film and the insulating film including the interlayer insulating film covering the metal film (the gate electrode), can be reduced.

The SiON film or the amorphous Si film as the stress-reducing film does not affect the characteristics of the transistor, so that the reliability of the gate electrode can be improved without deteriorating the characteristics of the transistor.

The reaction-preventing film interposed between the metal film and the poly-Si film prevents reaction between the metal film and the poly-Si film and enhances the adhesion between the metal film and the poly-Si film, which improves the reliability of the gate electrode.

Since a part of the gate insulating film exposed after the formation of the opening is removed, and then the gate insulating film is deposited again in the opening, the part of the gate insulating film damaged during the formation of the opening can be removed and the undamaged gate insulating film can be formed.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-48631, filed on Feb. 25, 2002 including specification, claims, drawings and summary, on which the Convention priority of the present application is based, are incorporated herein by reference in its entirety.

1. A semiconductor device comprising:
a gate insulating film formed on a semiconductor substrate;
a interlayer insulating film formed over said gate insulating film and provided with an opening in which a part of said gate insulating film is exposed; and
a gate electrode formed on said gate insulating film exposed in said opening,
wherein said gate electrode is a metal film having side surfaces coated with a stress-reducing film.

2. The semiconductor device according to claim 1, wherein said stress-reducing film is a poly-Si film not containing any impurity.

3. The semiconductor device according to claim 1, wherein said stress-reducing film is a poly-Si film containing an impurity.

4. The semiconductor device according to claim 3, wherein thickness of a part of said gate insulating film underlying said stress-reducing film is greater than that of a part of said gate insulating film underlying said metal film.

5. The semiconductor device according to claim 3, wherein said stress-reducing film is formed so as to cover side surfaces and a bottom surface of said metal film.

6. The semiconductor device according to claim 1, wherein said stress-reducing film is a SiON film or an amorphous Si film.

7. The semiconductor device according to claim 1, wherein a reaction-preventing film is interposed between said metal film and said stress-reducing film.
